(19) United States
(12) Patent Application Publication
(10) Pub. No.: US 2026/0150408 A1
(43) Pub. Date: May 28, 2026

(54) ELECTROSTATIC DISCHARGE DEVICE THYRISTORS WITH NANOSHEET GATES

(71) Applicant: INTERNATIONAL BUSINESS MACHINES CORPORATION, ARMONK, NY (US)

(72) Inventors: Robert Gauthier, Williston, VT (US); Anthony I-Chih Chou, Guilderland, NY (US); Anindya Nath, Watervliet, NY (US); Masoud Zabihi, Schenectady, NY (US)

(21) Appl. No.: 18/957,575

(22) Filed: Nov. 22, 2024

(51) Int. Cl. H01L 27/02; H01L 21/762; H01L 21/8238; H01L 27/092; H01L 29/06

(52) U.S. Cl. CPC H10D 89/713; H10D 62/121; H10D 84/0172; H10D 84/0191; H10D 84/038; H10D 84/85; H10W 10/014; H10W 10/17

(57) ABSTRACT

A semiconductor device includes a p-n junction including a P-type doped region and an N-typed doped region, an N-well region, a P-well region. The p-n junction is located between the N-well region and the P-well region. The semiconductor device further includes a set of shallow trench isolation (STI) below the p-n junction, the N-well region and the P-well region. There is no STI between an anode region and a cathode region of the p-n junction.

### BACKGROUND

### Technical Field

The present disclosure generally relates to semiconductors, and more particularly, to semiconductors with nanosheet gate structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a P-type doped region and an N-typed doped region, an N-well region, a P-well region. The p-n junction is located between the N-well region and the P-well region. The semiconductor device further includes a set of shallow trench isolation (STI) below the p-n junction, the N-well region and the P-well region. There is no STI between an anode region and a cathode region of the p-n junction.

In an embodiment, the semiconductor device is an electrostatic discharge silicon controlled rectifier device.

In an embodiment, the semiconductor device includes a set of gate regions on opposite ends of the p-n junction, the N-well region and the P-well region.

In an embodiment, the semiconductor device includes a first well region and a second well region adjacent to each other and below the p-n junction, the N-well region and the P-well region, and a substrate below the first well region and the second well region.

In an embodiment, each of the p-n junction, the N-well region and the P-well region further includes a plurality of nano-sheet gates between a corresponding doped region and a gate region.

In an embodiment, the plurality of nano-sheet gates includes alternative layers extended horizontally between the corresponding doped region and the gate region.

In an embodiment, the alternative layers include silicon.

According to an embodiment, a method of fabricating a semiconductor device includes forming a p-n junction comprising a P-type doped region and an N-typed doped region, forming an N-well region, forming a P-well region, wherein the p-n junction is located between the N-well region and the P-well region, and forming a set of shallow trench isolation (STI) below the p-n junction, the N-well region and the P-well region. There is no STI between an anode region and a cathode region of the p-n junction.

In an embodiment, the semiconductor device is an electrostatic discharge silicon controlled rectifier device.

In an embodiment, the method incudes forming a set of gate regions on opposite ends of the p-n junction, the N-well region and the P-well region.

In an embodiment, the method incudes forming a first well region and a second well region adjacent to each other and below the p-n junction, the N-well region and the P-well region, and forming a substrate below the first well region and the second well region.

In an embodiment, the forming each of the p-n junction, the N-well region and the P-well region further includes forming plurality of nano-sheet gates extended horizontally between a corresponding doped region and a gate region.

In an embodiment, the plurality of nano-sheet gates includes silicon.

According to an embodiment, a semiconductor device includes a p-n junction comprising a P-type doped region and an N-typed doped region, an N-well region, a P-well region, and a set of shallow trench isolation (STI) below the p-n junction, the N-well region and the P-well region. The p-n junction is located between the N-well region and the P-well region. An anode region and a cathode region of the p-n junction are isolated by a STI of the set of STI.

In an embodiment, the semiconductor device is an electrostatic discharge silicon controlled rectifier device.

In an embodiment, the semiconductor device includes a set of gate regions on opposite ends of the p-n junction, the N-well region and the P-well region.

In an embodiment, the semiconductor device includes a first well region and a second well region adjacent to each other and below the p-n junction, the N-well region and the P-well region, and a substrate below the first well region and the second well region.

In an embodiment, each of the p-n junction, the N-well region and the P-well region further includes a plurality of nano-sheet gates between a corresponding doped region and a gate region.

In an embodiment, the plurality of nano-sheet gates comprises alternative layers extended horizontally between the corresponding doped region and the gate region.

In an embodiment, the semiconductor device includes the alternative layers include silicon.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1A illustrates a sideview of a planar complementary metal oxide semiconductor device.

FIG. 1B illustrates exemplary circuitry of the planar complementary metal oxide semiconductor device as shown in FIG. 1A.

FIG. 1C illustrates an I-V chart for the planar complementary metal oxide semiconductor device as shown in FIG. 1A.

FIG. 2A illustrates an electrostatic discharge device without isolation between anode and cathode, in accordance with an embodiment.

FIG. 2B illustrates exemplary circuitry of the planar complementary metal oxide semiconductor device as shown in FIG. 2A.

FIG. 2C illustrates an I-V chart for the planar complementary metal oxide semiconductor device as shown in FIG. 2A.

FIG. 3 illustrates an electrostatic discharge device with isolation between anode and cathode, in accordance with an embodiment.

FIG. 4A illustrates a diode/bipolar string triggered electrostatic discharge device without isolation between anode and cathode, in accordance with an embodiment.

FIGS. 4B-4D illustrate exemplary circuitry of the planar complementary metal oxide semiconductor device as shown in FIG. 4A.

FIG. 4E illustrates an I-V chart for the planar complementary metal oxide semiconductor device as shown in FIG. 4A.

FIG. 5 illustrates a top view of a diode/bipolar string triggered electrostatic discharge device without isolation between anode and cathode, in accordance with an embodiment.

FIG. 6 illustrates a diode/bipolar string triggered electrostatic discharge device with isolation between anode and cathode, in accordance with an embodiment.

FIG. 7 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments. In foundry technology, it is important that typical electrostatic discharge (ESD) devices are designed to meet the requirements of various input/output (I/O) types. Among these, vertical bipolar transistors play a crucial role. Vertical bipolars are utilized in ESD protection schemes due to their ability to handle high current densities and provide rapid response times during an ESD event, and allow for efficient dissipation of ESD energy, thereby safeguarding sensitive components within integrated circuits.

Another important class of ESD protection devices includes thyristor structures, specifically NPNP or PNPN configurations, commonly known as silicon-controlled rectifiers (SCRs). These devices leverage the latching behavior inherent in thyristors to maintain conduction during an ESD event. Once triggered, they provide a low-resistance path for the ESD current, effectively shunting it away from vulnerable circuit elements until the current falls below a certain holding threshold.

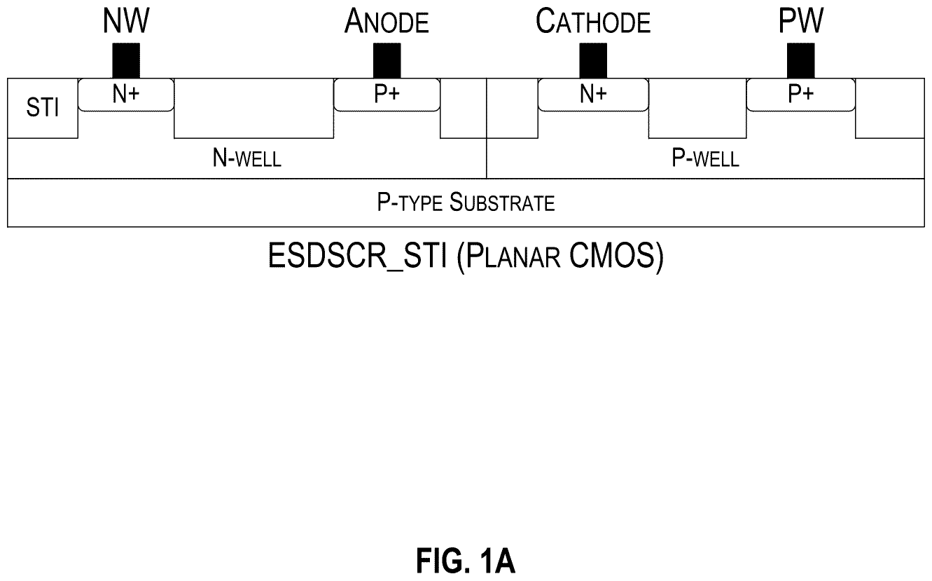

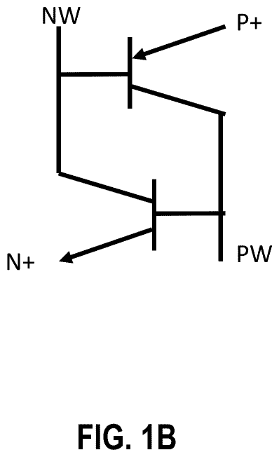

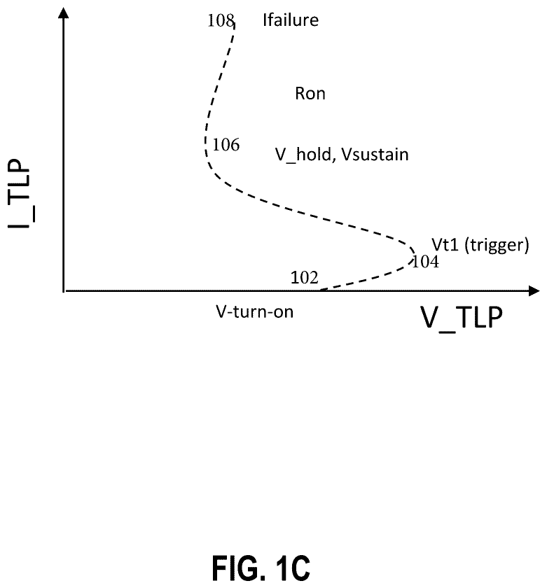

FIG. 1A illustrates a sideview of a planar complementary metal oxide semiconductor device. A planar complementary metal-oxide-semiconductor (CMOS) semiconductor devices are commonly used in integrated circuits. As shown in FIG. 1A, the transistor operates with the current flowing from the emitter to the collector, with the base controlling this current flow. In this type of transistor, the emitter is heavily doped with P-type, or N-type impurities to create a high concentration of holes or electrons, which are positive charge carriers/negative charges. A Planar CMOS STI bound PNPN silicon controlled rectifier (SCR), commonly referred to as a thyristor, is a semiconductor device integrated within a CMOS technology platform. This device leverages the standard planar CMOS fabrication processes, incorporating STI to achieve effective electrical isolation between adjacent components on the chip.

The PNPN SCR includes four alternating layers of P-type and N-type semiconductor material arranged in a planar configuration: P-type, N-type, P-type, and N-type. This sequence forms two interconnected bipolar junction transistors (BJTs)—a PNP transistor and an NPN transistor—that are coupled in such a way that the operation of one influences the other. The STI surrounds the SCR structure laterally, providing isolation from other circuit elements and preventing unwanted leakage currents and electrical interference. Under normal operating conditions, the PNPN SCR remains in a high-resistance, non-conducting state. The device is essentially “off” because the internal PN junctions are not forward-biased sufficiently to allow significant current flow. The SCR requires a triggering event to transition to the “on” state. This triggering can occur either by applying a voltage across the device that exceeds its breakover voltage or by injecting a small gate current into the device to initiate conduction.

When the applied voltage surpasses the breakover voltage, or a sufficient gate current is introduced, the SCR undergoes a regenerative switching action. The initial small current flow causes the first transistor (for example, the PNP transistor) to begin conducting, which increases the current through its base-emitter junction. This increase enhances the base current of the second transistor (the NPN transistor), causing it to conduct more heavily. The conduction of the NPN transistor, in turn, further increases the base current of the PNP transistor. This positive feedback loop rapidly drives both transistors into full conduction, resulting in the SCR switching to a low-resistance, conducting state. In this “on” state, the device allows a large current to flow between the anode and cathode with minimal voltage drop across it.

The role of the STI in this structure is critical for device performance and reliability. The STI provides lateral electrical isolation by surrounding the PNPN SCR structure with a dielectric material, typically silicon dioxide. This isolation confines the current flow within the SCR during operation, preventing it from affecting adjacent devices on the chip. It also helps to control the triggering characteristics and the holding current of the SCR by influencing the distribution of electric fields within the device. During an ESD event, the device can swiftly transition to the conducting state in response to the sudden voltage spike or injected current. Once “on,” the SCR provides a low-resistance path for the high ESD current, diverting it away from sensitive components in the integrated circuit. The STI ensures that this large current is confined within the SCR, minimizing the risk of thermal damage or latch-up in other parts of the chip.

After the ESD event subsides and the current through the SCR falls below a certain threshold known as the holding current, the device resets to its original high-resistance, non-conducting state. This automatic resetting is crucial for the normal operation of the integrated circuit, as it ensures that the SCR does not remain in the conducting state and inadvertently short the power supply rails. The design of the planar CMOS STI-bound PNPN SCR allows it to be integrated seamlessly into standard CMOS processes without requiring significant alterations to the fabrication flow. This compatibility makes it an attractive solution for on-chip ESD protection in modern integrated circuits, where space is at a premium, and the complexity of adding additional protection components needs to be minimized.

FIG. 1B illustrates exemplary circuitry of the planar complementary metal oxide semiconductor device as shown in FIG. 1A. FIG. 1C illustrates an I-V chart for the planar complementary metal oxide semiconductor device as shown in FIG. 1A. The regions of operation of a planar CMOS STI-bound PNPN SCR/Thyristor can be described in terms of its distinct electrical behavior under varying voltage and current conditions. The device transitions through four primary regions: leakage (pre-turn-on, shown as region 102), trigger (turn-on, shown as region 104), holding (sustaining, shown as region 106), and failure (shown as region 108).

In the leakage or pre-turn-on region, the device remains in a high-impedance state, conducting only a minimal leakage current. This phase occurs when the voltage across the SCR is below the trigger voltage Vtrigger or Vt1, and the junctions of the thyristor are not forward-biased sufficiently to allow significant current flow. The current in this region is typically in the nanoampere range, ensuring that the device does not interfere with the normal operation of the circuit under standard conditions. This phase is defined by the device's ability to isolate itself electrically while maintaining readiness to activate when required.

The trigger or turn-on region begins when the voltage across the device exceeds the trigger voltage Vt1. At this point, the device transitions from a high-impedance to a low-impedance state. The base-emitter junctions of the PNPN structure become forward-biased, and carriers are injected across the junctions, initiating a regenerative feedback loop. This process results in a rapid increase in current flow, as depicted by the steep rise in the I-V curve. The trigger voltage is a critical parameter as it defines the point at which the device activates to protect the circuit from overvoltage events or transient surges.

In the holding or sustaining region, the SCR maintains its conductive state with a relatively low voltage drop across the device. This region is characterized by the holding voltage Vholding, which is lower than the trigger voltage. The current flow is sustained by the positive feedback mechanism of the PNPN structure, ensuring efficient conduction of large currents. The slope of the I-V curve in this region is determined by the on-resistance Ron, which is a key parameter affecting the power dissipation and efficiency of the device. Lower Ron values result in better performance, as they minimize voltage drop and energy loss during conduction. This region ensures safe and effective dissipation of the transient energy while protecting the circuit.

The failure region occurs when the voltage or current exceeds the device's maximum capacity, defined by the failure voltage Vfail or Vt2 and failure current Ifail or It2. In this region, the device may experience thermal runaway, junction breakdown, or other catastrophic failures. The I-V curve typically shows a sharp drop in current as the device loses its ability to conduct. The failure voltage and current are key parameters that determine the maximum tolerances of the SCR, providing insights into the robustness and reliability of the device under extreme conditions.

The load capacitance Cload is another critical parameter that influences the SCR's dynamic behavior. It represents the capacitance seen by the device in the circuit and affects the speed and responsiveness of the SCR during the trigger phase. High Cload values can slow the turn-on response, potentially impacting the device's ability to protect against fast transient events. Optimizing Cload is essential for ensuring that the SCR responds promptly to voltage surges while maintaining stability during normal operation. Together, these regions of operation and key parameters define the performance characteristics of the Planar CMOS STI-bound PNPN SCR/Thyristor, ensuring it functions effectively in demanding applications where precise current and voltage control are required.

Disclosed is a semiconductor device with STI employed to electrically isolate adjacent devices on a semiconductor wafer to enhance the performance and reliability. By etching shallow trenches into the silicon substrate and filling them with dielectric material, such as silicon dioxide, STI effectively prevents electrical crosstalk and leakage currents between neighboring devices. Such an isolation is particularly important in high-density integrated circuits where device proximity can lead to interference and reduced performance. The semiconductor device further utilizes floating gate boundaries as conductive regions surrounded by insulating material, which can effectively isolate the conductive regions electrically from the rest of the circuit. In the disclosed semiconductor device, floating gates can influence the electric fields within the device, aiding in controlling the triggering mechanisms of thyristor structures. Such a control enhances the robustness of the ESD protection by improving the device's ability to handle sudden voltage spikes without inadvertently triggering during normal operation.

As the semiconductor industry advances towards the 2-nanometer (2 nm) technology node, the physical dimensions of devices shrink significantly, leading to new challenges in ESD protection. Smaller geometries result in reduced breakdown voltages and tighter design margins, making traditional ESD protection strategies less effective or incompatible.

Accordingly, the teachings herein provide methods and systems of lateral electrostatic discharge device with nanosheet gates. The techniques described herein may be implemented in a number of ways. Example implementations are provided below with reference to the following figures.

### Example Semiconductor Device With Nanosheet Gate Structure

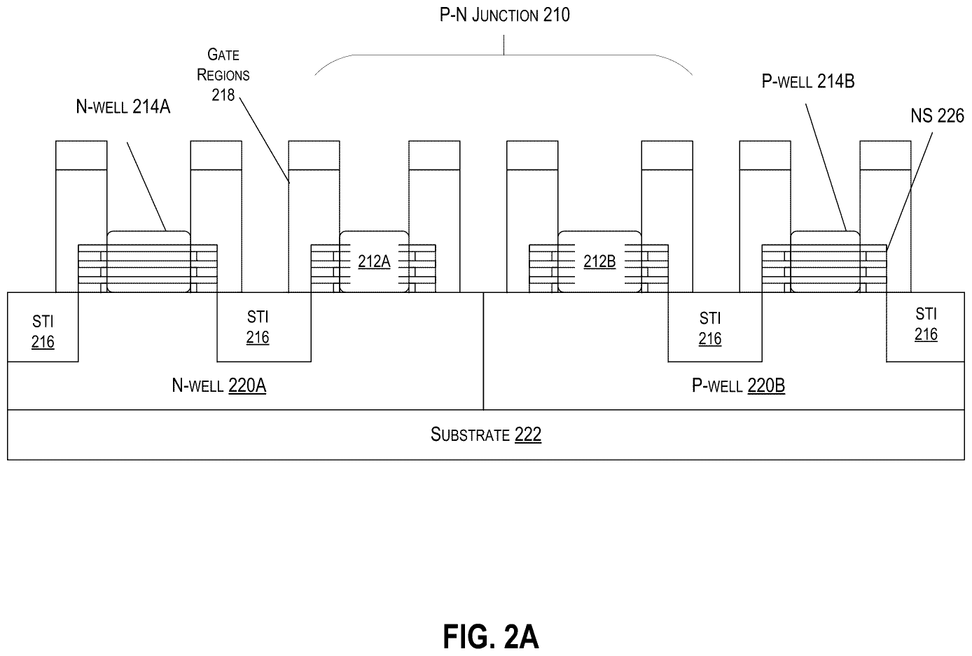

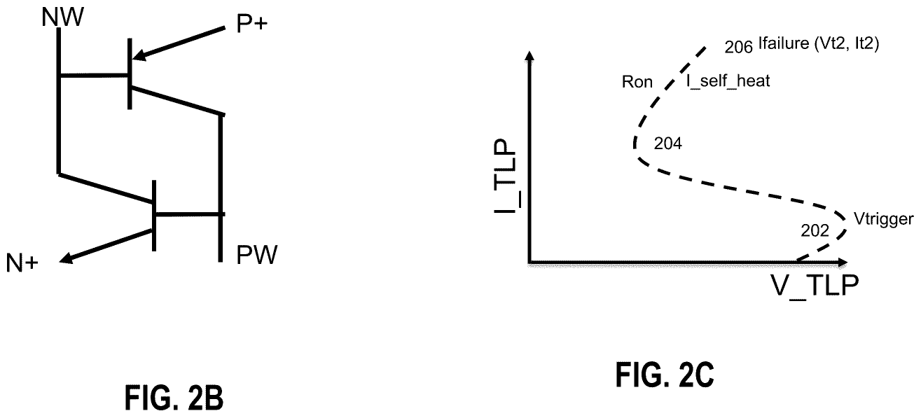

Reference now is made to FIGS. 2A-2C, which provide a cross-section view, a schematic view, and a graph, respectively, of a semiconductor device, consistent with illustrative embodiments. FIG. 2A illustrates an electrostatic discharge device without isolation between anode and cathode, in accordance with an embodiment. FIG. 2B illustrates exemplary circuitry of the planar complementary metal oxide semiconductor device as shown in FIG. 2A. FIG. 2C illustrates an I-V chart for the planar complementary metal oxide semiconductor device as shown in FIG. 2A. Regions 202, 204 and 206 are similar to the regions 102, 106 and 108 as describe in FIG. 1C, respectively.

The semiconductor device includes a p-n junction 210 composed of a P-type doped region 212A and an N-type doped region 212B. The p-n junction 210 serves as the central component, enabling controlled movement of charge carriers—holes in the P-type doped region 212A and electrons in the N-type doped region 212B—which is fundamental to the device's operation.

Each of the P-type doped region 212A and the N-type doped region 212B can be created by doping with a type P dopant, which introduces an excess of positive charge carriers (holes), or with a type N dopant, which introduces an excess of negative charge carriers (electrons). A P-type doped region and an N-type doped region can form the p-n junction of the semiconductor device. The p-n junction can control the flow of electrical current within the semiconductor device. The p-n junction can be created by doping two adjacent regions, one with a type P dopant, which introduces an excess of positive charge carriers (holes), and the other with a type N dopant, which introduces an excess of negative charge carriers (electrons). At the interface between the P and N regions, a depletion region forms due to the diffusion of electrons from the N region into the P region and the diffusion of holes in the opposite direction. Such a diffusion process continues until the electric field created by the accumulation of charge at the junction balances the diffusion forces, resulting in a zone depleted of free charge carriers. In its natural state, the p-n junction allows current to flow more easily in one direction than in the opposite.

When forward biased, i.e., positive voltage applied to the P side relative to the N side, the depletion region narrows, lowering the barrier for charge carriers to move across the junction, and allowing current to flow through the device. Conversely, when reverse-biased, i.e., negative voltage applied to the P side, the depletion region widens, increasing the barrier for charge movement, and significantly reducing the flow of current. In some embodiments, the N-well region 220A and the P-well region 220B can form on two sides of the STI 216, which can facilitate the control of threshold voltages and channel formation in the semiconductor device.

Adjacent to the p-n junction 210 are an N-well region 214A and a P-well region 214B. The p-n junction 210 is located between these two well regions. The N-well region 214A is doped with donor impurities to create an excess of electrons, while the P-well region 214B is doped with acceptor impurities to provide an abundance of holes. The well regions extend the functionality of the p-n junction 210 by influencing the electrical characteristics of the device, such as threshold voltage and current flow, and help in isolating the p-n junction from other parts of the semiconductor substrate.

Beneath the p-n junction 210, the N-well region 214A, and the P-well region 214B, there is a set of shallow trench isolation, STI 216. The STI 216 is an insulating layer which can be made of silicon dioxide, formed by etching shallow trenches into the substrate and filling them with the dielectric material. Such an isolation technique prevents electrical crosstalk and leakage currents between different regions of the device, ensuring reliable and efficient operation. In some embodiments, there is no STI between the anode region and the cathode region of the p-n junction 210, allowing for direct electrical interaction necessary for the device's functionality.

The semiconductor device functions as an electrostatic discharge (ESD) silicon-controlled rectifier (SCR). An SCR is a four-layer semiconductor device (PNPN) that acts as a switch, capable of moving from a non-conducting state to a conducting state when triggered. In the context of ESD protection, the SCR quickly shunts excess voltage away from sensitive components during an ESD event, safeguarding the integrity of the integrated circuit.

On opposite ends of the p-n junction 210, the N-well region 214A, and the P-well region 214B, there is a set of gate regions 218. The set of gate regions 218 control the flow of charge carriers by modulating the electric field within the device. By applying a voltage to the gates, the conductivity of the underlying channel can be altered, allowing for precise control over the device's switching behavior. This feature enhances the device's responsiveness and efficiency, particularly in high-speed applications.

Below the p-n junction 210, the N-well region 214A, and the P-well region 214B, there are a first well region 220A and a second well region 220B situated adjacent to each other. The well regions provide additional doping profiles and structural support, further refining the electrical characteristics and isolation within the device. A substrate 222 lies beneath these well regions, forming the foundational layer upon which the entire semiconductor device is built.

Each of the p-n junction 210, the N-well region 214A, and the P-well region 214B includes a plurality of nanosheet gates, NS 226, positioned between the corresponding doped region and a gate region. The NS 226 can include ultra-thin semiconductor layers that offer enhanced electrostatic control over the device's channels. The use of nanosheet technology allows for better scaling and performance by reducing short-channel effects and improving gate control, which is critical in advanced semiconductor devices.

The NS 226 can include alternating layers that extend horizontally between the doped regions and the gate regions. These alternating layers include materials such as silicon, chosen for its superior semiconductor properties like high carrier mobility and compatibility with existing fabrication processes. The horizontal extension of these layers increases the effective channel width without enlarging the device's footprint, resulting in higher drive currents and improved overall performance. In some embodiments, the semiconductor device includes STI isolated junctions. In some embodiments, the semiconductor device includes non-STI bound junctions, e.g., just silicon between junctions.

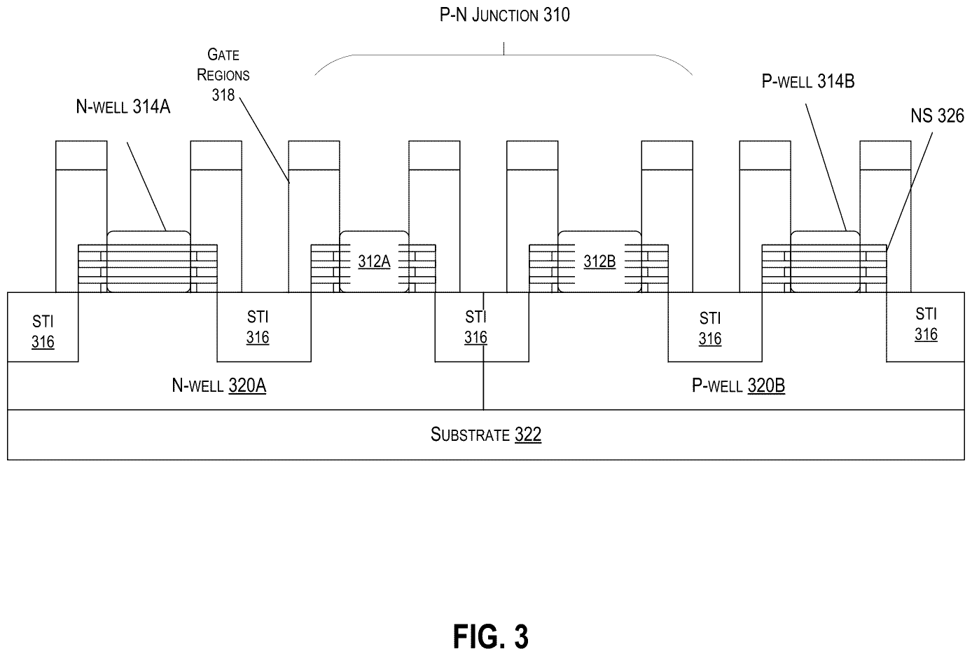

FIG. 3 illustrates an electrostatic discharge device with isolation between anode and cathode, in accordance with an embodiment. The semiconductor device can be structured around a p-n junction 310 that includes a P-type doped region 312A and an N-type doped region 312B. This junction serves as the fundamental component of the device, enabling controlled movement of charge carriers—holes in the P-type region and electrons in the N-type region—which is essential for the device's operation. The ESD device can further include an N-well 320A, a P-well 320B and STI 326.

Adjacent to the p-n junction 310 are an N-well region 314A and a P-well region 314B. The p-n junction 310 is strategically located between these two well regions. The N-well region 314A is doped with donor impurities to create an excess of electrons, while the P-well region 314B is doped with acceptor impurities to provide an abundance of holes. This arrangement enhances the electrical characteristics of the device by influencing factors such as threshold voltage and current flow, and it aids in isolating the p-n junction from other parts of the semiconductor substrate. Beneath the p-n junction 310, the N-well region 314A, and the P-well region 314B lies a set of STI, STI 316. The STI is an insulating layer, typically composed of silicon dioxide, formed by etching shallow trenches into the substrate and filling them with the dielectric material. This isolation technique prevents electrical crosstalk and leakage currents between different regions of the device, ensuring reliable and efficient operation. In this design, the anode region and the cathode region of the p-n junction are isolated from each other by one of the STI structures in the set. This isolation is crucial for controlling the flow of current within the device and preventing unintended interactions between the anode and cathode.

The semiconductor device functions as an electrostatic discharge (ESD) silicon-controlled rectifier (SCR). An SCR is a four-layer semiconductor device (PNPN) that acts as a switch, capable of transitioning from a non-conducting state to a conducting state when triggered. In the context of ESD protection, the SCR rapidly shunts excess voltage away from sensitive components during an ESD event, safeguarding the integrity of the integrated circuit. On opposite ends of the p-n junction 310, the N-well region 314A, and the P-well region 314B, there is a set of gate regions 318. The set of gate regions 318 control the flow of charge carriers by modulating the electric field within the device. Applying a voltage to the gates alters the conductivity of the underlying channel, allowing for precise control over the device's switching behavior. This feature enhances responsiveness and efficiency, particularly important in high-speed applications where rapid switching is necessary.

Below the p-n junction 310, the N-well region 314A, and the P-well region 314B, there are a first well region 330A and a second well region 330B situated adjacent to each other. The well regions provide additional doping profiles and structural support, further refining the electrical characteristics and isolation within the device. A substrate 322 lies beneath these well regions, forming the foundational layer upon which the entire semiconductor device is built. Each of the p-n junction 310, the N-well region 314A, and the P-well region 314B includes a plurality of nanosheet gates, NS 324, positioned between the corresponding doped region and a gate region. These nanosheet gates include ultra-thin semiconductor layers that offer enhanced electrostatic control over the device's channels. The use of nanosheet technology allows for better scaling and performance by reducing short-channel effects and improving gate control, which is critical in advanced semiconductor devices.

The NS 324 includes alternating layers that extend horizontally between the doped regions and the gate regions. The alternating layers include silicon, chosen for its semiconductor properties such as high carrier mobility and compatibility with existing fabrication processes. The horizontal extension of these layers increases the effective channel width without enlarging the device's footprint, resulting in higher drive currents and improved overall performance.

In some embodiments, the semiconductor device is an integration of a p-n junction, well regions, shallow trench isolation, gate regions, and nanosheet gate technology. Its design as an ESD silicon-controlled rectifier makes it effective for protecting electronic circuits from voltage spikes caused by electrostatic discharge.

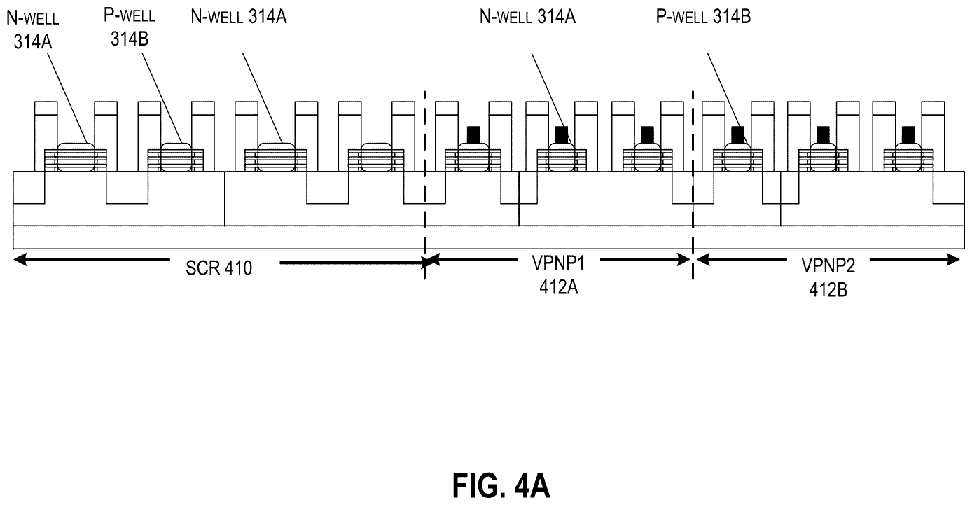

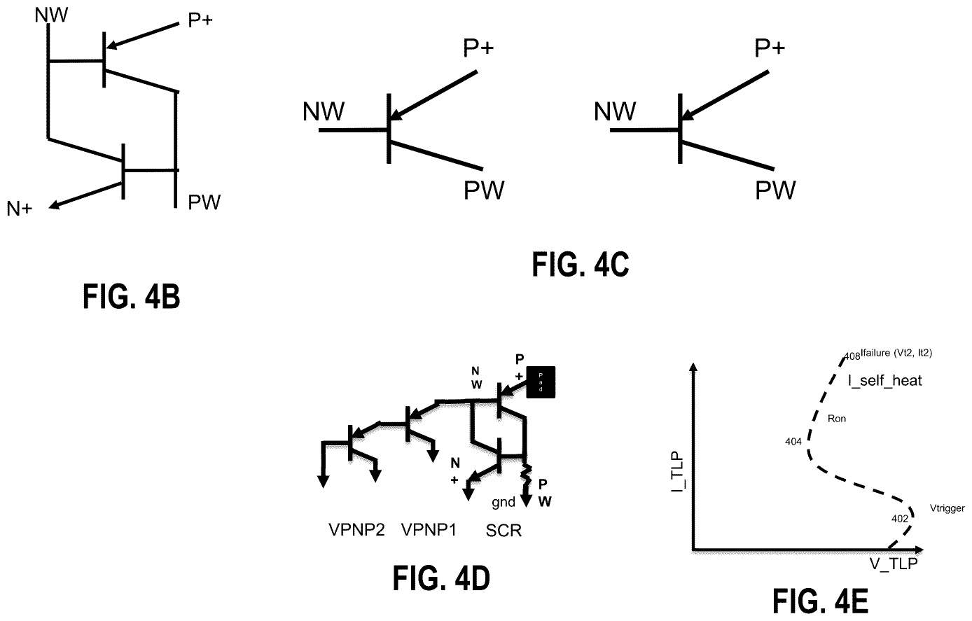

FIG. 4A illustrates a diode/bipolar string triggered electrostatic discharge device without isolation between anode and cathode, in accordance with an embodiment. FIG. 4B-4D illustrate exemplary circuitry of the planar complementary metal oxide semiconductor device as shown in FIG. 4A. FIG. 4E illustrates an I-V chart for the planar complementary metal oxide semiconductor device as shown in FIG. 4A. Regions denoted as 402, 404, and 406 are similar to the regions 102, 106, and 108 as described in FIG. 1C, respectively. As shown in FIG. 4A, the semiconductor device can include an SCR 410, a first vertical PNP, VPNP1 412A, and a second vertical PNP, VPNP2 412B, adjacent to each other. The diode/bipolar string triggered silicon controlled rectifier (DTSCR) shown in FIG. 4A is an electrostatic discharge (ESD) protection device that combines an SCR with a triggering mechanism involving diodes or bipolar transistors. In the configuration without isolation between the anode and cathode, the DTSCR utilizes the inherent properties of the SCR and two VPNP transistors connected to each other to provide effective ESD protection.

The SCR can be a four-layer semiconductor structure with alternating P-type and N-type regions, e.g., P-type region 416A and N-type region 416B, forming a PNPN configuration, which behaves as a switch that remains non-conductive under normal operating conditions but can rapidly transition to a conductive state when triggered, allowing it to conduct high currents with low voltage drop. Such a characteristic makes the SCR suitable for shunting the high currents associated with ESD events away from sensitive circuit components. In the DTSCR without isolation between the anode and cathode, the lack of isolation means there are no physical barriers such as STI 418 separating the anode and cathode. This direct connection allows for efficient current flow during an ESD event, enabling the device to respond swiftly.

The two VPNP transistors are connected in such a way that they facilitate the triggering of the SCR. Each VPNP transistor includes an PNP structure where the current flows vertically through the layers. The transistors are integrated into the SCR structure, with their emitters and collectors connected to the anode 420A and cathode 420B, respectively.

During normal operation, the DTSCR remains in a high-impedance, non-conductive state, and the VPNP transistors are not active. The voltage levels across the device are insufficient to forward-bias the junctions required for conduction. As a result, the DTSCR does not interfere with the regular operation of the circuit. When an ESD event occurs, a sudden surge of voltage is applied across the anode and cathode of the DTSCR. The high voltage causes the base-emitter junctions of the VPNP transistors to become forward-biased. The VPNP transistors begin to conduct, allowing current to flow from the emitter to the collector. The current flowing through the VPNP transistors injects charge carriers into the base regions of the parasitic bipolar transistors within the SCR structure.

The injection of carriers effectively lowers the potential barrier at the PN junctions of the SCR, initiating a regenerative feedback mechanism. The conduction of the VPNP transistors increases the voltage drop across their base-emitter junctions, which in turn forward-biases the base-emitter junctions of the internal PNP and NPN transistors that constitute the SCR. As these internal transistors begin to conduct, they reinforce each other's conduction through positive feedback, rapidly driving the SCR into a low-impedance, conductive state. Once the SCR is triggered, it provides a low-resistance path for the ESD current to flow from the anode to the cathode, which allows the high current associated with the ESD event to bypass the sensitive circuitry, preventing damage to the integrated circuit components. The absence of isolation between the anode and cathode regions facilitates this rapid transition by allowing charge carriers to move freely without impediment, ensuring a swift response to the ESD event.

After the ESD event subsides and the current flowing through the SCR drops below a certain threshold known as the holding current, the SCR reverts to its high-impedance, non-conductive state. The automatic resetting is crucial for the normal operation of the circuit, as it prevents the SCR from remaining in a conductive state that could short the power supply rails or disrupt circuit functionality. In this configuration, the DTSCR effectively leverages the properties of both the SCR and the VPNP transistors to provide robust ESD protection. The VPNP transistors act as triggering mechanisms that respond to the high voltages of an ESD event by initiating the conduction of the SCR. The lack of isolation between the anode and cathode ensures that there are no barriers to the rapid flow of current necessary for the SCR to trigger and conduct effectively. The integration of the VPNP transistors with the SCR in a configuration without isolation simplifies the device structure and can reduce fabrication complexity. It should be noted that, the semiconductor device can include VNPN instead of VPNP.

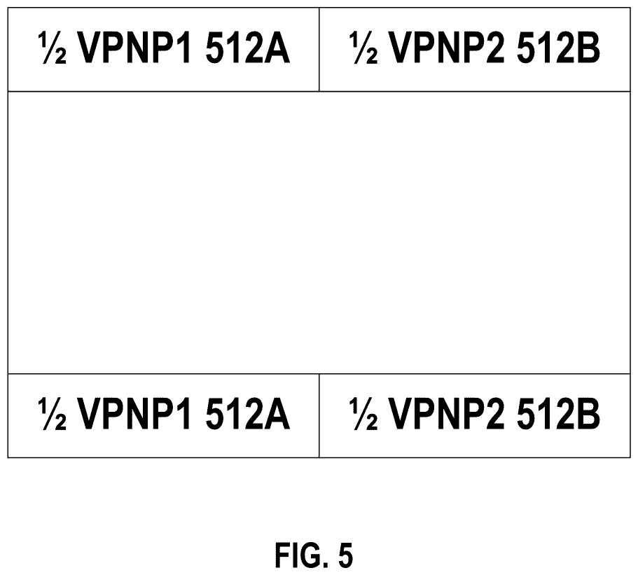

FIG. 5 illustrates a top view of a diode/bipolar string triggered electrostatic discharge device without isolation between anode and cathode, in accordance with an embodiment. As shown, the semiconductor device includes a full size SCR 510 between two VPNP, VPNP 512A and VPNP 512B, which cover both sides of the SCR 510.

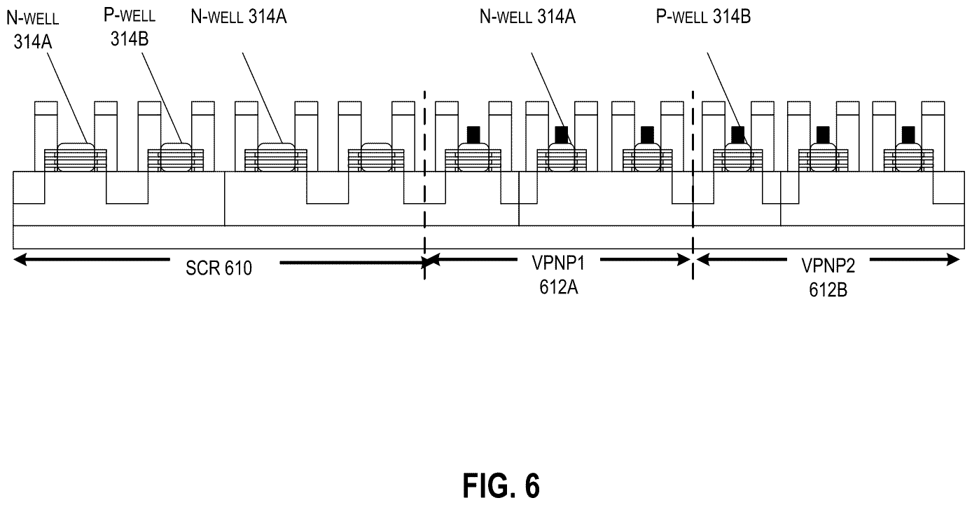

FIG. 6 illustrates a diode/bipolar string triggered electrostatic discharge device with isolation between anode and cathode, in accordance with an embodiment. As shown in FIG. 6, the semiconductor device can include an SCR 610, a first vertical PNP, VPNP1 612A, and a second vertical PNP, VPNP2 612B, adjacent to each other. The diode/bipolar string triggered silicon controlled rectifier (DTSCR) shown in FIG. 6 is an electrostatic discharge (ESD) protection device that combines an SCR with a triggering mechanism involving diodes or bipolar transistors. The isolation between the anode 620A and cathode 620B is achieved using STI 618 or deep well regions, which electrically separate these regions within the semiconductor substrate.

In this configuration, the SCR includes a four-layer PNPN structure formed by alternating P-type and N-type semiconductor regions. The anode 620A is connected to the outer P+ region, and the cathode 620B is connected to the outer N+ region. The middle N and P regions serve as the bases and collectors of the internal PNP and NPN transistors that make up the SCR. The isolation between the anode 620A and cathode 620B prevents direct electrical interaction under normal operating conditions, reducing leakage currents and preventing unintended triggering of the SCR.

The two VPNP transistors are integrated into the structure to facilitate the triggering of the SCR during an ESD event. Each VPNP transistor is an PNP transistor with vertical current flow, and they are connected in such a way that their emitters and collectors are associated with the anode and cathode regions, respectively. Under normal operating conditions, the DTSCR remains in a high-resistance, non-conductive state, and the VPNP transistors are inactive because the voltage levels are insufficient to forward-bias their junctions. The STI 618 ensures that no significant current flows between the anode and cathode, allowing the device to remain inactive during normal circuit operation.

When an ESD event occurs, a sudden high-voltage spike is applied across the anode 620A and cathode 620B of the DTSCR. This high voltage causes the base-emitter junctions of the VPNP transistors to become forward-biased. The VPNP transistors begin to conduct, allowing current to flow from their emitters to their collectors. This conduction injects current into the base regions of the internal transistors within the SCR. The injected currents effectively reduce the potential barriers at the PN junctions of the SCR, initiating a regenerative feedback mechanism where the internal PNP and NPN transistors begin to conduct more heavily. This positive feedback rapidly drives the SCR into a low-resistance, conductive state.

Once the SCR is triggered, it provides a low-impedance path between the anode and cathode, allowing the ESD current to be safely shunted away from sensitive components in the integrated circuit. The isolation, e.g., STI 618, between the anode 620A and cathode 620B confines the high ESD current within the SCR, preventing it from affecting adjacent circuitry and enhancing the device's reliability. After the ESD event subsides and the current through the SCR decreases below a certain holding current threshold, the SCR reverts to its high-resistance, non-conductive state. The VPNP transistors also turn off as the voltage drops below their conduction thresholds, allowing normal operation of the integrated circuit to resume without interruption. The isolation between the anode and cathode in this DTSCR configuration prevents unintended triggering during normal operation, enhancing device reliability, and improving ESD performance. By controlling the triggering parameters and ensuring that the SCR activates only during an ESD event, the DTSCR provides effective protection for the integrated circuit while maintaining normal circuit functionality.

In some embodiments, it will be understood that other types as the substrate, other than silicon, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

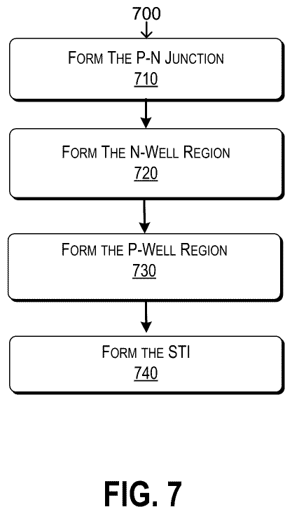

FIG. 7 illustrates a block diagram of a method 700 for forming the semiconductor device, in accordance with some embodiments. As shown by block 710, a p-n junction is formed. The p-n junction includes a P-type doped region and an N-typed doped region;

As shown by block 720, an N-well region is formed.

As shown by block 730, a P-well region is formed. The p-n junction is located between the N-well region and the P-well region; and

As shown by block 740, a set of shallow trench isolation is formed below the p-n junction, the N-well region and the P-well region.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a p-n junction comprising a P-type doped region and an N-type doped region;
an N-well region;
a P-well region, wherein the p-n junction is located between the N-well region and the P-well region; and
a set of shallow trench isolation (STI) below the p-n junction, the N-well region and the P-well region, wherein there is no STI between an anode region and a cathode region of the p-n junction.

2. The semiconductor device of claim 1, wherein the semiconductor device is an electrostatic discharge silicon controlled rectifier device.

3. The semiconductor device of claim 1, further comprising a set of gate regions on opposite ends of the p-n junction, the N-well region and the P-well region.

4. The semiconductor device of claim 1, further comprising:
a first well region and a second well region adjacent to each other and below the p-n junction, the N-well region and the P-well region; and
a substrate below the first well region and the second well region.

5. The semiconductor device of claim 1, wherein each of the p-n junction, the N-well region and the P-well region further comprises a plurality of nano-sheet gates between a corresponding doped region and a gate region.

6. The semiconductor device of claim 5, wherein the plurality of nano-sheet gates comprises alternative layers extended horizontally between the corresponding doped region and the gate region.

7. The semiconductor device of claim 6, wherein the alternative layers include silicon.

8. A method of fabricating a semiconductor device, the method comprising:
forming a p-n junction comprising a P-type doped region and an N-type doped region;
forming an N-well region;
forming a P-well region, wherein the p-n junction is located between the N-well region and the P-well region; and
forming a set of shallow trench isolation (STI) below the p-n junction, the N-well region and the P-well region, wherein there is no STI between an anode region and a cathode region of the p-n junction.

9. The method of claim 8, wherein the semiconductor device is an electrostatic discharge silicon controlled rectifier device.

10. The method of claim 8, further comprising:
forming a set of gate regions on opposite ends of the p-n junction, the N-well region and the P-well region.

11. The method of claim 8, further comprising:
forming a first well region and a second well region adjacent to each other and below the p-n junction, the N-well region and the P-well region; and
forming a substrate below the first well region and the second well region.

12. The method of claim 8, wherein forming each of the p-n junction, the N-well region and the P-well region further comprises:
forming plurality of nano-sheet gates extended horizontally between a corresponding doped region and a gate region.

13. The method of claim 12, wherein the plurality of nano-sheet gates includes silicon.

14. A semiconductor device, comprising:
a p-n junction comprising a P-type doped region and an N-type doped region;
an N-well region;
a P-well region, wherein the p-n junction is located between the N-well region and the P-well region; and
a set of shallow trench isolation (STI) below the p-n junction, the N-well region and the P-well region, wherein an anode region and a cathode region of the p-n junction are isolated by a STI of the set of STI.

15. The semiconductor device of claim 14, wherein the semiconductor device is an electrostatic discharge silicon controlled rectifier device.

16. The semiconductor device of claim 14, further comprising a set of gate regions on opposite ends of the p-n junction, the N-well region and the P-well region.

17. The semiconductor device of claim 14, further comprising:
a first well region and a second well region adjacent to each other and below the p-n junction, the N-well region and the P-well region; and
a substrate below the first well region and the second well region.

18. The semiconductor device of claim 14, wherein each of the p-n junction, the N-well region and the P-well region further comprises a plurality of nano-sheet gates between a corresponding doped region and a gate region.

19. The semiconductor device of claim 18, wherein the plurality of nano-sheet gates comprises alternative layers extended horizontally between the corresponding doped region and the gate region.

20. The semiconductor device of claim 19, wherein the alternative layers include silicon.
